(19) United States
(12) Patent Application Publication
(10) Pub. No.: US 2014/0014962 A1
(43) Pub. Date: Jan. 16, 2014

(54) DISPLAY DEVICE AND PIXEL DEFECT CORRECTING METHOD

(71) Applicant: Panasonic Liquid Crystal Display Co., Ltd., Himeji-shi (JP)

(72) Inventors: Takeshi ARAI, Hyogo (JP); Kunihiko WATANABE, Hyogo (JP)

(21) Appl. No.: 13/938,893

(22) Filed: Jul. 10, 2013

(30) Foreign Application Priority Data
Jul. 11, 2012 (JP) 2012-155954

(51) Int. Cl. H01L 33/00

(52) U.S. Cl. CPC H01L 33/0041
USPC 257/59

(57) ABSTRACT

A display device includes a plurality of pixels formed in a matrix pattern by partition with a plurality of gate lines and a plurality of data lines. The plurality of pixels are connected to the plurality of gate lines and the plurality of data lines. At least a part of the plurality of pixels includes a transistor, a pixel electrode connected to the transistor, a common electrode arranged so as to be opposed to the pixel electrode, and a correction transistor portion. The correction transistor portion includes a gate electrode portion that is formed of a part of the common electrode and transmits visible light, a semiconductor active portion that transmits visible light, a drain electrode portion that forms a drain electrode, and a source electrode portion that forms a source electrode.

### CROSS-REFERENCE TO RELATED APPLICATION

The present application claims priority from Japanese Application JP 2012-155954 filed on Jul. 11, 2012. The content of the Japanese Application is hereby incorporated by reference into this application.

### BACKGROUND OF THE INVENTION

1. Field of the Invention

The present invention relates to a display device and a pixel defect correcting method.

2. Description of the Related Art

Generally, in a liquid crystal display device, a display region is formed of a plurality of pixels, and one TFT is provided for each of the pixels. However, in a process of forming the pixels, it is necessary to perform fine processing, and hence, in some cases, a defect is generated in a part of the pixels.

To address this problem, there has been known a pixel defect correcting method in which the following pixels are used. That is, for example, two TFTs are provided in one pixel. In a case where one TFT (general TFT) is short-circuited to generate a bright spot, the TFT is cut off and the other TFT (auxiliary TFT) is used (see Japanese Patent Application Laid-open No. JP 05-341316 A).

### SUMMARY OF THE INVENTION

However, when the auxiliary TFT is provided in addition to the general TFT in one pixel as described above, it is necessary to shield an active layer of the auxiliary TFT from light, and hence it is necessary to arrange a gate metal in the pixel. As a result, the transmittance of the pixel is reduced. It is further conceivable to provide the auxiliary TFT on gate wiring together with the general TFT, but particularly in a high-definition display device, arrangement onto the gate wiring is difficult in some cases.

In view of the above, one object of one or more embodiments of the present invention is to provide a display device that is capable of, even when a defect is generated in the pixel, correcting the pixel defect while preventing a reduction of a transmittance, and to provide a pixel defect correcting method.

(1) In one or more embodiments of the present invention, a display device includes a plurality of pixels formed in a matrix pattern by partition with a plurality of gate lines and a plurality of data lines. The plurality of pixels are connected to the plurality of gate lines and the plurality of data lines. At least a part of the plurality of pixels includes a transistor, a pixel electrode connected to the transistor, a common electrode arranged so as to be opposed to the pixel electrode, and a correction transistor portion. The correction transistor portion includes a gate electrode portion that is formed of a part of the common electrode and transmits visible light, a semiconductor active portion that transmits visible light, a drain electrode portion that forms a drain electrode, and a source electrode portion that forms a source electrode.

(2) In the display device according to (1), corresponding one of the plurality of pixels is driven by a correction transistor that is formed by cutting off corresponding one of the plurality of data lines from the pixel electrode, and in the correction transistor portion, cutting off the gate electrode portion from the common electrode, connecting the gate electrode portion to corresponding one of the plurality of gate lines, connecting the source electrode portion to corresponding one of the plurality of data lines, and connecting the drain electrode portion to the pixel electrode.

(3) In the display device according to (2), the correction transistor portion further includes a source connection pad for connecting the source electrode portion to the corresponding one of the plurality of data lines, and a gate connection pad for connecting the gate electrode portion to the corresponding one of the plurality of gate lines.

(4) In the display device according to (3), the source connection pad is formed in the same layer as the plurality of gate lines, and the gate connection pad is formed in the same layer as the drain electrode portion and the source electrode portion.

(5) In the display device according to (2), the correction transistor portion further includes a gate wiring portion for connecting the gate electrode portion to the corresponding one of the plurality of gate lines, and a data wiring portion for connecting the source electrode portion to the corresponding one of the plurality of data lines.

(6) In the display device according to (1), the pixel electrode includes a plurality of opening portions. The drain electrode portion and the source electrode portion of the correction transistor portion are arranged along the plurality of opening portions.

(7) In the display device according to (1), the correction transistor portion is provided so as to overlap above corresponding one of the plurality of gate lines.

(8) In the display device according to (1), the semiconductor active portion is made of an amorphous oxide semiconductor.

(9) In one or more embodiments of a pixel defect correcting method for a display device, the display device includes a plurality of pixels formed in a matrix pattern by partition with a plurality of gate lines and a plurality of data lines is included. The plurality of pixels are connected to the plurality of gate lines and the plurality of data lines. The display device also includes at least a part of the plurality of pixels including a transistor, a pixel electrode connected to the transistor, a common electrode arranged so as to be opposed to the pixel electrode, and a correction transistor portion. The correction transistor includes a gate electrode portion that is formed of a part of the common electrode and transmits visible light, a semiconductor active portion that transmits visible light, a drain electrode portion that forms a drain electrode, and a source electrode portion that forms a source electrode. The pixel defect correcting method includes cutting off corresponding one of the plurality of data lines from the pixel electrode, cutting off the gate electrode portion from the common electrode, connecting the gate electrode portion to corresponding one of the plurality of gate lines, connecting the source electrode portion to corresponding one of the plurality of data lines, and connecting the drain electrode portion to the pixel electrode.

(10) In one or more embodiments of the present invention, a display device includes a plurality of pixels formed in a matrix pattern by partition with a plurality of gate lines and a plurality of data lines. The plurality of pixels are connected to the plurality of gate lines and the plurality of data lines. At least a part of the plurality of pixels includes a transistor, a pixel electrode connected to the transistor, a common electrode arranged so as to be opposed to the pixel electrode, a semiconductor layer that is formed in a part between the common electrode and the pixel electrode and transmits visible light, and two conductive layers formed on the semiconductor layer.

(11) In one or more embodiments of the present invention, a display device includes a plurality of pixels formed in a matrix pattern by partition with a plurality of gate lines and a plurality of data lines. The plurality of pixels are connected to the plurality of gate lines and the plurality of data lines. Apart of the plurality of pixels includes a pixel electrode, a common electrode arranged so as to be opposed to the pixel electrode, and a correction transistor connected to the pixel electrode. The correction transistor includes a gate electrode formed in the same layer and of the same material as the common electrode, a semiconductor active portion that transmits visible light, a drain electrode, and a source electrode.

### BRIEF DESCRIPTION OF THE DRAWINGS

In the accompanying drawings:

FIG. 1 is a schematic view illustrating a display device according to an embodiment of the present invention;

FIG. 2 is a conceptual diagram of a pixel circuit formed on a TFT substrate illustrated in FIG. 1;

FIG. 3 is a view illustrating a correction transistor portion;

FIG. 4 is a schematic sectional view taken along the line IV-IV of FIG. 3;

FIG. 5 is a schematic sectional view taken along the line V-V of FIG. 3;

FIG. 6 is a schematic sectional view taken along the line VI-VI of FIG. 3;

FIG. 7 is a view illustrating a pixel defect correcting method;

FIG. 8 is a view illustrating the pixel defect correcting method;

FIG. 9 is a view illustrating the pixel defect correcting method;

FIG. 10 is a view illustrating a first modified example of the present invention;

FIG. 11 is a view illustrating a second modified example of the present invention; and

FIG. 12 is a view illustrating the second modified example of the present invention.

### DETAILED DESCRIPTION OF THE INVENTION

Now, one or more embodiments of the present invention is described referring to the accompanying drawings. In the drawings, the same or equivalent components are denoted by the same reference numerals, and the overlapping description thereof is herein omitted.

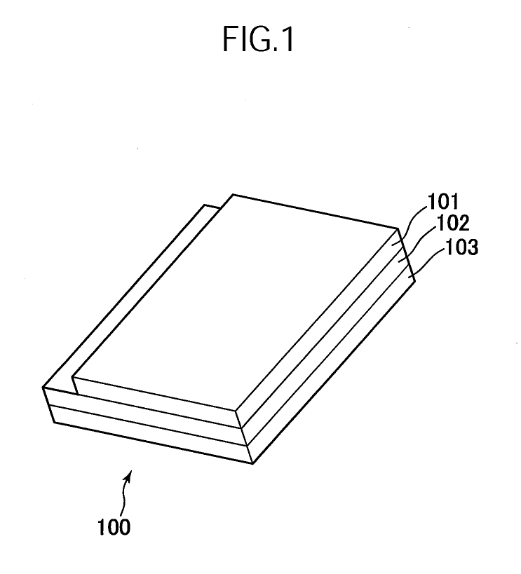

FIG. 1 is a schematic view illustrating a display device according to the embodiment of the present invention. As illustrated in FIG. 1, a display device 100 includes, for example, a thin film transistor (TFT) substrate 102 and a filter substrate 101. On the TFT substrate 102, TFTs and the like (not shown) are formed. The filter substrate 101 is opposed to the TFT substrate 102 and is provided with color filters (not shown). The display device 100 also includes a liquid crystal material (not shown) and a backlight unit 103. The liquid crystal material is sealed in a region that is sandwiched between the TFT substrate 102 and the filter substrate 101. The backlight unit 103 is provided on the TFT substrate 102 so as to be held in contact with a surface opposite to the side on which the filter substrate 101 is provided.

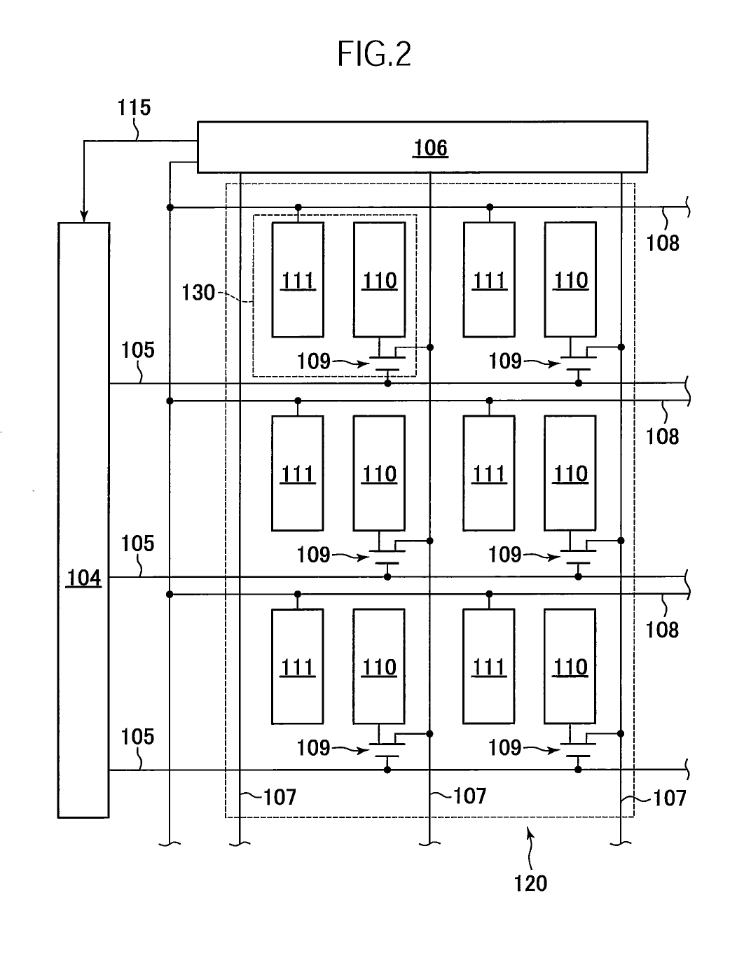

FIG. 2 is a conceptual diagram of a pixel circuit formed on the TFT substrate illustrated in FIG. 1. As illustrated in FIG. 2, the TFT substrate 102 includes a plurality of gate lines 105 and a plurality of source lines 107. The gate lines 105 are arranged at approximately equal intervals in the lateral direction of FIG. 2. The source lines 107 are arranged at approximately equal intervals in the vertical direction of FIG. 2. The gate lines 105 are connected to a shift register circuit 104, whereas the source lines 107 are connected to a driver 106.

The shift register circuit 104 includes a plurality of basic circuits (not shown) respectively corresponding to the plurality of gate lines 105. Each of the basic circuits includes a plurality of TFTs and capacitors. Each of the basic circuits outputs a gate signal to a corresponding one of the gate lines 105 in response to a control signal 115 from the driver 106. A voltage of the gate signal becomes high during a corresponding gate scanning period (HIGH-signal period) of one frame period and becomes low during the remaining period (LOW-signal period).

Pixel regions 130 are formed in a matrix pattern by partition with the gate lines 105 and the source lines 107. Each of the pixel regions 130 includes a TFT 109, a pixel electrode 110, and a common electrode 111. Agate of the TFT 109 is connected to a corresponding one of the gate lines 105. One of a source and a drain is connected to a corresponding one of the source lines 107, whereas the other one is connected to the pixel electrode 110. The common electrode 111 is connected to a corresponding one of common signal lines 108. The pixel electrode 110 and the common electrode 111 are provided so as to be opposed to each other.

Note that, as described later, although not illustrated in FIG. 2, each of the pixels 130 includes, as an auxiliary TFT of the TFT 109, a correction transistor portion 304 prepared in advance for a case where a defect is generated in the TFT 109. The correction transistor portion 304 functions as a correction transistor 700 when a pixel defect correcting method to be described later is carried out. Details of the correction transistor portion 304 and the correction transistor 700 are described later.

Next, a schematic operation of the pixel circuit configured as described above is described. The driver 106 applies a reference voltage to the common electrodes 111 through the common signal lines 108. The shift register circuit 104 controlled by the driver 106 outputs a gate signal to the gate of the TFTs 109 through the gate lines 105. Further, the driver 106 supplies a voltage of a video signal to the TFTs 109, to which the gate signal is output, through the source lines 107. The voltage of the video signal is applied to the pixel electrodes 110 through the TFTs 109. At this time, potential differences are generated between the pixel electrodes 110 and the common electrodes 111.

The driver 106 controls the potential differences to control the orientation of liquid crystal molecules of the liquid crystal material inserted between the pixel electrodes 110 and the common electrodes 111. Light from the backlight unit 103 is guided to the liquid crystal material. Therefore, by controlling the orientation of the liquid crystal molecules as described above, the amount of light from the backlight unit 103 can be adjusted. As a result, an image can be displayed. Note that, the operation of the case where the correction transistor 700 is used instead of the TFT 109 is similar to the above, and hence the description thereof is omitted.

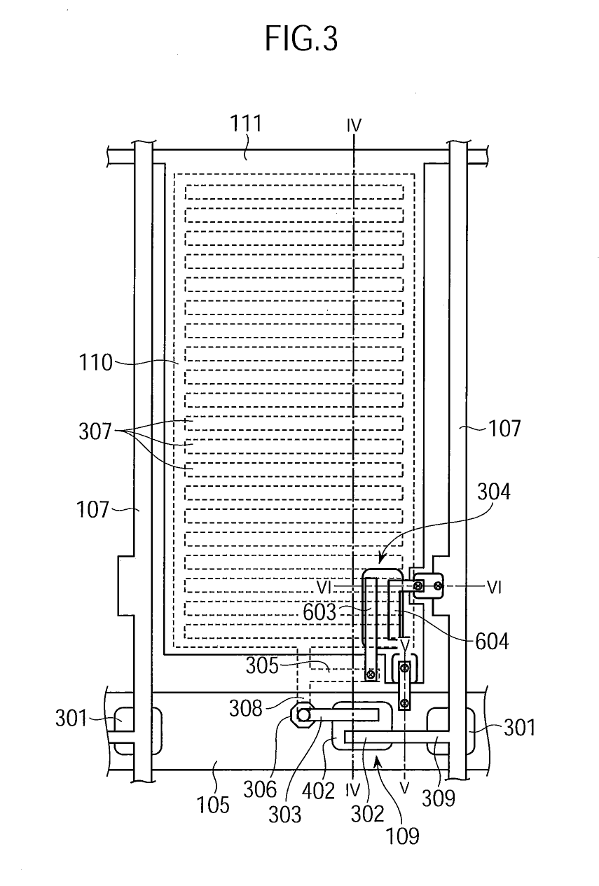

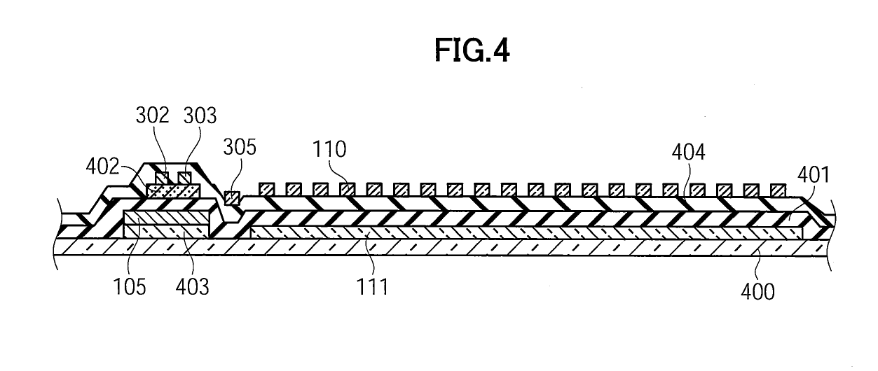

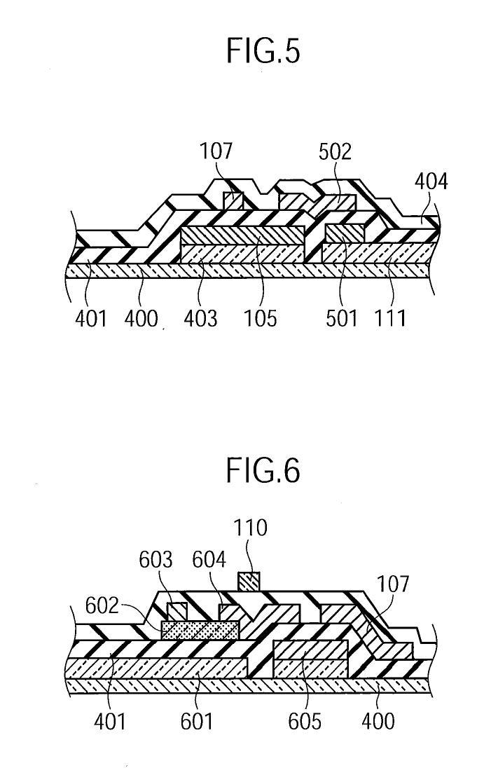

FIG. 3 is a view illustrating the correction transistor portion. Specifically, FIG. 3 is a schematic enlarged view illustrating the vicinity of the pixel 130 illustrated in FIG. 2. Further, FIG. 4 schematically illustrates a cross-section taken along the line IV-IV of FIG. 3. FIG. 5 schematically illustrates a cross-section taken along the line V-V of FIG. 3, and FIG. 6 schematically illustrates a cross-section taken along the line VI-VI of FIG. 3. Note that, the configuration illustrated in FIGS. 3 to 5 is merely an example, and this embodiment is not limited to the configuration illustrated in those figures. Further, in FIG. 3, for the sake of easy understanding of the description, the pixel electrode 110 is indicated by broken lines.

As illustrated in FIG. 3, within a pixel region that is a region surrounded by the gate lines 105 and the source lines 107, the common electrode 111 and the pixel electrode 110 are arranged, and further, the correction transistor portion 304 that forms the correction transistor 700 when the pixel defect is corrected as described later is arranged.

As illustrated in FIG. 3, the gate line 105 has an opening portion 301 in a part that intersects with the source line 107. Further, in a region in which the opening portion 301 is formed, the source line 107 is formed so as to extend in the lateral direction of FIG. 3 to be connected to a source electrode 302 of the TFT 109. In other words, the source electrode 302 is formed as a part of the source line 107, for example.

The TFT 109 is formed on the gate line 105. Specifically, as illustrated in FIG. 4, a semiconductor active layer 402 is arranged above the gate line 105 through intermediation of a gate insulating film 401, and the source electrode 302 and a drain electrode 303 are arranged on the semiconductor active layer 402. In other words, for example, apart of the gate line 105 corresponds to a gate electrode of the TFT 109. Note that, as illustrated in FIGS. 4 and 5, the gate line 105 is formed on an underlayer 403 formed in the same layer as the common electrode 111, for example. Further, the common electrode 111 and the like are formed on a substrate 400, for example.

The correction transistor portion 304 is formed so that the correction transistor portion 304 can function as an auxiliary TFT (correction transistor 700) when an abnormality occurs in the TFT 109. Further, as illustrated in FIG. 3, the correction transistor portion 304 is arranged within the pixel region that is the region surrounded by the gate lines 105 and the source lines 107. Further, as illustrated in FIGS. 3 and 6, the correction transistor portion 304 mainly includes a gate electrode portion 601 formed of a part of the common electrode 111, a semiconductor active portion 602, a drain electrode portion 603, and a source electrode portion 604. Note that, as illustrated in FIG. 6, the source electrode portion 604 is extended up to a position above a source connection pad 605 to be described later.

The gate electrode portion 601 of the correction transistor portion 304 is formed of a part of the common electrode 111. In other words, as illustrated in FIG. 3, a part of the end portion of the common electrode 111 in the vicinity of the TFT 109 corresponds to the gate electrode portion 601. Therefore, the gate electrode portion 601 transmits visible light, and is formed of, for example, a transparent conductive film similarly to the common electrode 111.

The semiconductor active portion 602 of the correction transistor portion 304 is formed above the gate electrode portion 601 through intermediation of the gate insulating film 401. The semiconductor active portion 602 also transmits visible light, and is formed of, for example, an amorphous oxide semiconductor (transparent amorphous oxide semiconductor (TAOS)).

On the semiconductor active portion 602, the drain electrode portion 603 and the source electrode portion 604 are formed. As illustrated in FIG. 6, the source electrode portion 604 is extended toward the source line 107 and partially formed so as to overlap above the source connection pad 605 in sectional view. Further, a part of the source line 107 is arranged so as to overlap above the source connection pad 605 in sectional view as well. Note that, the source connection pad 605 is formed in the same layer as a layer in which the gate line 105 is formed, for example. Further, the drain electrode portion 603 and the source electrode portion 604 are each a conductive layer, and are made of, for example, a metal such as Cu.

As illustrated in FIG. 3, the drain electrode portion 603 of the correction transistor portion 304 is extended toward the TFT 109, and is partially arranged so as to overlap above a drain connection pad 305 in sectional view, the drain connection pad 305 being formed by extending the pixel electrode 110. Note that, as illustrated in FIG. 3, the drain connection pad 305 is formed by extending a part of the pixel electrode 110. In other words, the drain connection pad 305 is electrically connected to the pixel electrode 110. Further, the drain connection pad 305 is electrically connected to the drain electrode 303 of the TFT 109 via a through hole 306.

In the pixel region, the pixel electrode 110 is arranged so as to be opposed to the common electrode 111. Specifically, as illustrated in FIG. 4, the pixel electrode 110 is arranged above the common electrode 111 through intermediation of the gate insulating film 401 and a protective film 404 in the stated order from the lower side of FIG. 4. Further, as illustrated in FIGS. 3 and 4, the pixel electrode 110 is provided with a plurality of rectangular slits 307. Note that, the arrangement, the size, and the shape of the slits 307 are exemplary, and this embodiment is not limited to the arrangement, the size, and the shape.

As illustrated in FIG. 5, a first gate connection pad 501 is formed on apart of the common electrode 111. Then, above the first gate connection pad 501, a second gate connection pad 502 is arranged through intermediation of the gate insulating film 401. The first gate connection pad 501 is formed in the same layer as the gate line 105, and the second gate connection pad 502 is formed in the same layer as the source electrode 302 and the drain electrode 303. Further, as illustrated in FIG. 5, the second gate connection pad 502 is arranged so that one end portion thereof is arranged so as to overlap above the gate line 105.

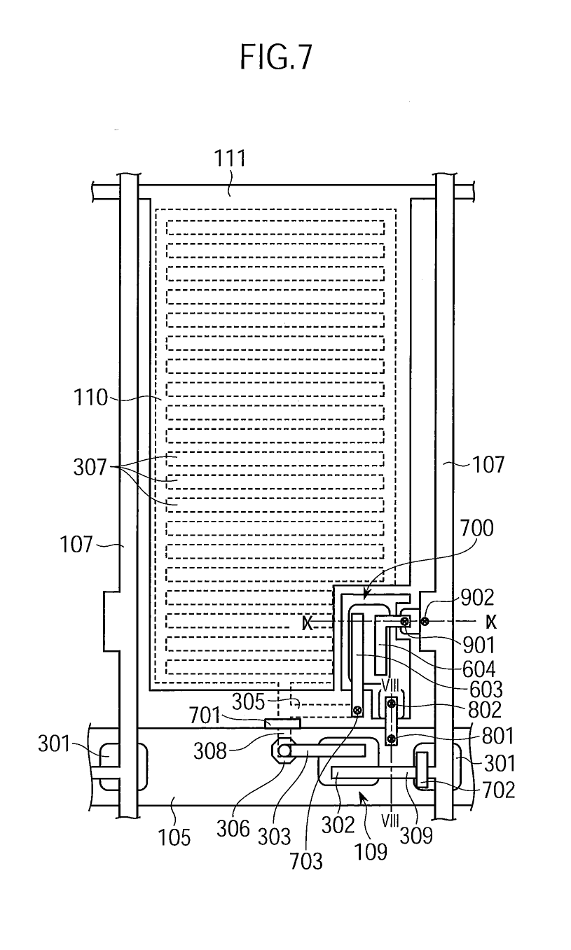

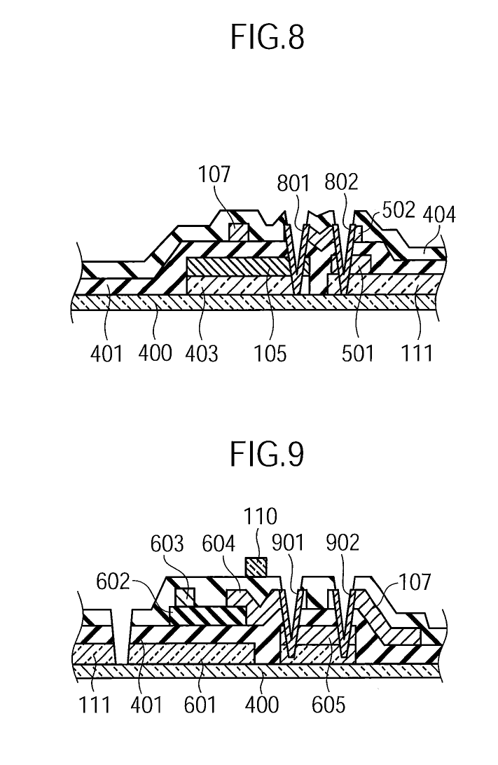

Next, with reference to FIGS. 7 to 9, the pixel defect correcting method in this embodiment is described. Note that, in this case, a case where a defect is generated in the TFT 109 illustrated in FIG. 7 is assumed. Further, FIGS. 7 to 9 correspond to views illustrating the states after the pixel defect is corrected of FIGS. 3, 5, and FIG. 6, respectively. In other words, FIG. 7 illustrates a state after the pixel defect correcting method is carried out in the pixel of FIG. 3. Further, FIG. 8 schematically illustrates a cross-section taken along the line VIII-VIII of FIG. 7, and FIG. 9 schematically illustrates a cross-section taken along the line IX-IX of FIG. 7.

When a defect is generated in the TFT 109, as illustrated in FIG. 7, the correction transistor portion 304 is cut off from the common electrode 111 by laser processing. Specifically, through laser processing, the common electrode 111 in the vicinity of the correction transistor portion 304 is removed, to thereby cut off the correction transistor portion 304.

Further, a part of a pixel electrode power feeding portion 308 that connects together the pixel electrode 110 and the drain electrode 303, and a part of a source electrode supply portion 309 are removed by laser processing. In this case, as illustrated in FIG. 7, the pixel electrode power feeding portion 308 corresponds to a part extending from the pixel electrode 110, that is, a part that connects together the pixel electrode 110 and the drain electrode 303 of the TFT 109. Further, the source electrode supply portion 309 corresponds to a part extending from the source line 107 toward the source electrode 302 of the TFT 109, that is, a part located above the opening portion 301 in the gate line. Note that, FIG. 7 illustrates parts of the pixel electrode power feeding portion 308 and the source electrode supply portion 309, which have been subjected to the laser removal processing, as removal portions 701 and 702, respectively.

Accordingly, the video signal from the source line 107 is not input to the TFT 109, and the output signal from the TFT 109 is not input to the pixel electrode 110. In other words, through the laser removal processing, the TFT 109 with abnormity is cut off from the pixel electrode 110 and the source line 107. Note that, description is made above of the case where the connection between the source line 107 and the TFT 109 is cut by the removal portion 702 and the connection between the TFT 109 and the pixel electrode 110 is cut by the removal portion 701, but this embodiment is not limited to this case. For example, the connection may be electrically cut by any one of the removal portion 701 and the removal portion 702.

Further, as illustrated in FIG. 8, parts of the second gate connection pad 502, which are formed above the gate line 105 and the first gate connection pad 501, are also subjected to laser processing, to thereby weld the gate line 105 and the second gate connection pad 502, and also weld the first gate connection pad 501 and the second gate connection pad 502. Note that, FIGS. 7 and 8 illustrate the welded parts as welded portions 801 and 802 in order. Thus, the gate electrode portion 601 of the correction transistor portion 304 is electrically connected to the gate line 105.

Further, as illustrated in FIG. 9, parts of the source electrode portion 604 and the source line 107, which are arranged so as to overlap above the source connection pad 605, are also subjected to laser processing, to thereby weld the source connection pad 605 and the source electrode portion 604, and also weld the source connection pad 605 and the source line 107. Thus, the source line 107 and the source electrode portion 604 of the correction transistor portion 304 are electrically connected to each other. Note that, FIGS. 7 and 9 illustrate the welded parts as welded portions 901 and 902 in order.

Further, although the sectional view is omitted, similarly, as illustrated in FIG. 7, also a part extending from the drain electrode portion 603 of the correction transistor portion 304, which is arranged so as to overlap above the drain connection pad 305, is welded to the pixel electrode 110 by laser processing. Note that, FIG. 7 illustrates the welded part as a welded portion 703. Thus, the pixel electrode 110 and the drain electrode portion 603 of the correction transistor portion 304 are electrically connected to each other.

With the laser processing as described above, from the correction transistor portion 304, the correction transistor 700 that functions as the auxiliary TFT of the TFT 109 is formed. Specifically, with the laser processing as described above, the gate electrode portion 601 of the correction transistor portion 304 becomes a gate electrode (correction gate electrode) of the correction transistor 700. In other words, the correction gate electrode corresponds to a part of the common electrode 111 before the correcting method is carried out. Further, the source electrode portion 604 and the drain electrode portion 603 of the correction transistor portion 304 become a source electrode (correction source electrode) and a drain electrode (correction drain electrode) of the correction transistor 700, respectively.

According to this embodiment, even when a defect is generated in the TFT 109 in a part of the pixels of the display device 100, the TFT 109 having the defect generated therein is cut off to form the correction transistor 700. Thus, the defect of the pixel can be corrected to obtain a normal pixel. In this case, the correction transistor 700 and the correction transistor portion 304 are formed in the pixel region. However, the correction gate electrode, the gate electrode portion 601, and the semiconductor active portion 602 forming the correction transistor 700 and the correction transistor portion 304 are made of, for example, transparent materials that transmit visible light, such as a transparent conductive film and an amorphous oxide semiconductor. Therefore, the aperture ratio can be prevented from being reduced in the pixel region.

The present invention is not limited to the embodiment, and various modifications may be made thereto. For example, the structure described in the embodiment may be replaced by substantially the same structure, a structure which has the same action and effect, or a structure which can achieve the same object.

### First Modified Example

Next, a first modified example of the present invention is described. This modified example mainly differs from the embodiment in the direction in which the correction transistor portion 304 is formed. Other points are similar to those in the embodiment, and description of those similar points is omitted.

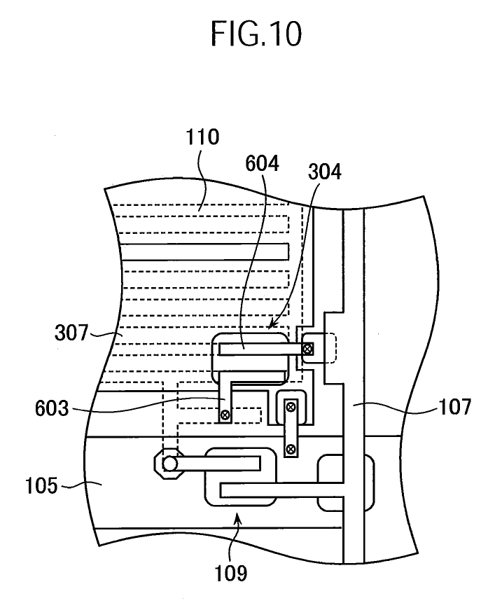

FIG. 10 is a view illustrating the modified example of the embodiment. Specifically, FIG. 10 is a schematic top view illustrating, in an enlarged manner, a region in the vicinity of the correction transistor portion 304 in this modified example. In this modified example, as illustrated in FIG. 10, the source electrode portion 604 and the drain electrode portion 603 of the correction transistor portion 304 are arranged along the slits 307 of the pixel electrode 110.

Specifically, as illustrated in FIG. 10, for example, the slits 307 of the pixel electrode 110 are arranged at approximately equal intervals in the lateral direction of FIG. 10. The source electrode portion 604 and the drain electrode portion 603 are arranged along, of the slits 307, the slit 307 located nearest to the TFT 109. According to this modified example, as compared to the embodiment, the influence of arranging the correction transistor portion 304 in the pixel region can be more reduced.

The present invention is not limited to the embodiment and this modified example, and various modifications may be made thereto. For example, the structure described in the embodiment may be replaced by substantially the same structure, a structure which has the same action and effect, or a structure which can achieve the same object.

### Second Modified Example

Next, a second modified example of the present invention is described. This modified example mainly differs from the first modified example in that correction wirings 121 and 124 are used for the connection between the gate electrode portion 601 of the correction transistor portion 304 and the gate line 105, and the connection between the source electrode portion 604 of the correction transistor portion 304 and the source line 107, respectively. Other points are similar to those in the first modified example and the embodiment, and description of those similar points is omitted.

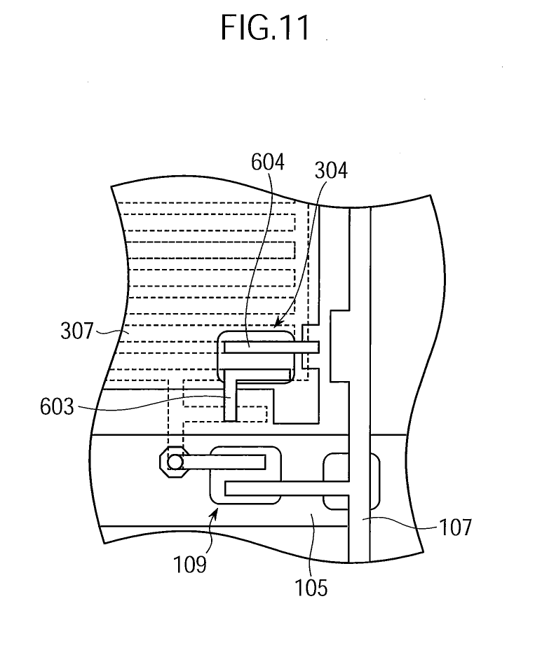

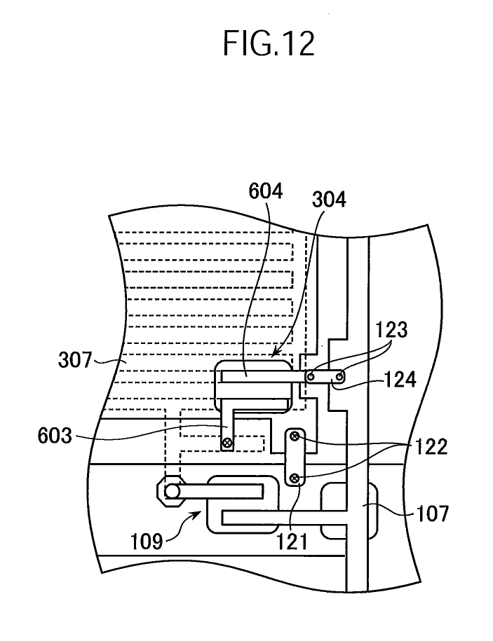

FIGS. 11 and 12 are views illustrating the second modified example of the present invention. Specifically, FIG. 11 is a schematic top view illustrating a part in the vicinity of the correction transistor portion 304 in this modified example. Further, FIG. 12 illustrates a state after the pixel defect correcting method is carried out in this modified example in FIG. 11.

As illustrated in FIG. 11, this modified example differs from the first modified example in that the first gate connection pad 501 and the second gate connection pad 502 are omitted, and further, the source connection pad 605 is omitted. Instead, when a defect is generated in the TFT 109, as illustrated in FIG. 12, the correction wirings 121 and 124 are used to connect the gate electrode portion 601 to the gate line 105, and connect the source electrode portion 604 to the source line 107.

Specifically, as illustrated in FIG. 12, contact holes 122 are respectively provided in the gate line 105, and in the gate insulating film 401 and the protective film 404 laminated on the common electrode 111. Then, the correction wiring 121 that connects the gate line 105 and the common electrode 111 is laminated, including the parts in which the contact holes 122 are formed.

Similarly, in the protective film 404 laminated on the source line 107 and the protective film 404 laminated on the source electrode portion 604 of the correction transistor portion 304, contact holes 123 are respectively provided, and the correction wiring 124 that connects the source electrode portion 604 and the source line 107 is laminated, including the parts in which the contact holes 123 are formed. The remaining pixel defect correcting method such as cutting off of the correction transistor portion 304 from the common electrode 111 and the laser removal of the parts of the pixel electrode power feeding portion 308 and the source electrode supply portion 309 of the TFT 109 is similar to that in the embodiment, and hence description thereof is omitted.

According to this modified example, as compared to the embodiment and the first modified example, it is unnecessary to provide, in advance, the first and second gate connection pads 501 and 502 or the source connection pad 605. In other words, when a pixel defect is generated, the TFT 109 is cut off and the correction transistor 700 is formed using the correction wirings 121 and 124. In this manner, the pixel can be normally operated with use of the correction transistor 700.

The present invention is not limited to the embodiment and the first and second modified examples, and various modifications may be made thereto. For example, the structure described in the embodiment may be replaced by substantially the same structure, a structure which has the same action and effect, or a structure which can achieve the same object. For example, in the second modified example, the correction transistor portion 304 is arranged in the same direction as in the first modified example, but the arrangement as described in the embodiment or other arrangements may be used.

Further, the embodiment and the first and second modified examples assume a case where the source electrode portion 604 (correction source electrode) and the drain electrode portion 603 (correction drain electrode) of the correction transistor portion 304 are made of a metal that is not transparent, such as Cu, but the source electrode portion 604 and the drain electrode portion 603 may alternatively be made of a transparent material such as a transparent conductive film. Further, the source electrode 302 and the drain electrode 303 of the TFT 109 may also be made of a transparent material such as a transparent conductive film, and the semiconductor active layer 402 of the TFT 109 may also be made of the material that transmits visible light (for example, amorphous oxide semiconductor). Further, in the above, a liquid crystal display device has been described as an example, but the present invention may be applied to a display device using other light emitting elements, such as an organic EL element, an inorganic EL element, and a field-emission device (FED). Further, in the above description, in order to facilitate the connection between the gate electrode portion 601 of the correction transistor 700 and the gate line 105, the end portion of the common electrode 111, at which the correction transistor portion 304 is formed, is extended toward the gate line 105 to form a rectangular region. However, the shape of the rectangular region is not limited to the above, and as along as the gate electrode portion 601 and the gate line 105 are connected to each other, the rectangular shape may be omitted, or a region having a different shape may be formed. Note that, the semiconductor layer in the scope of claims corresponds to the semiconductor active portion 602, for example, and the two conductive layers correspond to the drain electrode portion 603 and the source electrode portion 604, for example. Further, the data line in the scope of claims corresponds to the source line 107, for example.

What is claimed is:

1. A display device, comprising a plurality of pixels formed in a matrix pattern by partition with a plurality of gate lines and a plurality of data lines, the plurality of pixels being connected to the plurality of gate lines and the plurality of data lines,
wherein at least a part of the plurality of pixels comprises:
a transistor;
a pixel electrode connected to the transistor;
a common electrode arranged so as to be opposed to the pixel electrode; and
a correction transistor portion comprising:
a gate electrode portion that is formed of apart of the common electrode and transmits visible light;
a semiconductor active portion that transmits visible light;
a drain electrode portion that forms a drain electrode; and
a source electrode portion that forms a source electrode.

2. The display device according to claim 1, wherein corresponding one of the plurality of pixels is driven by a correction transistor that is formed by:
cutting off corresponding one of the plurality of data lines from the pixel electrode; and
in the correction transistor portion, cutting off the gate electrode portion from the common electrode, connecting the gate electrode portion to corresponding one of the plurality of gate lines, connecting the source electrode portion to corresponding one of the plurality of data lines, and connecting the drain electrode portion to the pixel electrode.

3. The display device according to claim 2, wherein the correction transistor portion further comprises:
a source connection pad for connecting the source electrode portion to the corresponding one of the plurality of data lines; and
a gate connection pad for connecting the gate electrode portion to the corresponding one of the plurality of gate lines.

4. The display device according to claim 3, wherein the source connection pad is formed in the same layer as the plurality of gate lines, and the gate connection pad is formed in the same layer as the drain electrode portion and the source electrode portion.

5. The display device according to claim 2, wherein the correction transistor portion further comprises:
a gate wiring portion for connecting the gate electrode portion to the corresponding one of the plurality of gate lines; and
a data wiring portion for connecting the source electrode portion to the corresponding one of the plurality of data lines.

6. The display device according to claim 1,
wherein the pixel electrode comprises a plurality of opening portions, and
wherein the drain electrode portion and the source electrode portion of the correction transistor portion are arranged along the plurality of opening portions.

7. The display device according to claim 1, wherein the correction transistor portion is provided so as to overlap above corresponding one of the plurality of gate lines.

8. The display device according to claim 1, wherein the semiconductor active portion is made of an amorphous oxide semiconductor.

9. A pixel defect correcting method for a display device, in which a plurality of pixels formed in a matrix pattern by partition with a plurality of gate lines and a plurality of data lines is included, and in which the plurality of pixels are connected to the plurality of gate lines and the plurality of data lines, the display device comprising:
at least a part of the plurality of pixels including;
a transistor,
a pixel electrode connected to the transistor,
a common electrode arranged so as to be opposed to the pixel electrode; and
a correction transistor portion including:
a gate electrode portion that is formed of a part of the common electrode and transmits visible light;
a semiconductor active portion that transmits visible light;
a drain electrode portion that forms a drain electrode; and
a source electrode portion that forms a source electrode,
the pixel defect correcting method comprising:
cutting off corresponding one of the plurality of data lines from the pixel electrode;
cutting off the gate electrode portion from the common electrode;
connecting the gate electrode portion to corresponding one of the plurality of gate lines;
connecting the source electrode portion to corresponding one of the plurality of data lines; and
connecting the drain electrode portion to the pixel electrode.

10. A display device, comprising a plurality of pixels formed in a matrix pattern by partition with a plurality of gate lines and a plurality of data lines, the plurality of pixels being connected to the plurality of gate lines and the plurality of data lines,
wherein at least a part of the plurality of pixels comprises:
a transistor;
a pixel electrode connected to the transistor;
a common electrode arranged so as to be opposed to the pixel electrode;
a semiconductor layer that is formed in a part between the common electrode and the pixel electrode and transmits visible light; and
two conductive layers formed on the semiconductor layer.

11. A display device, comprising a plurality of pixels formed in a matrix pattern by partition with a plurality of gate lines and a plurality of data lines, the plurality of pixels being connected to the plurality of gate lines and the plurality of data lines,
wherein a part of the plurality of pixels comprises:
a pixel electrode;
a common electrode arranged so as to be opposed to the pixel electrode; and
a correction transistor connected to the pixel electrode, and
wherein the correction transistor comprises:
a gate electrode formed in the same layer and of the same material as the common electrode;
a semiconductor active portion that transmits visible light;
a drain electrode; and
a source electrode.
